(19) United States
(12) Patent Application Publication
(10) Pub. No.: US 2021/0335937 A1
(43) Pub. Date: Oct. 28, 2021

(54) OLED DISPLAY PANEL

(71) Applicant: SHENZHEN CHINA STAR OPTOELECTRONICS SEMICONDUCTOR DISPLAY TECHNOLOGY CO., LTD, Shenzhen (CN)

(72) Inventor: Ming LIU, Shenzhen (CN)

(73) Assignee: SHENZHEN CHINA STAR OPTOELECTRONICS DISPLAY TECHNOLOGY CO., LTD., Shenzhen (CN)

(21) Appl. No.: 16/625,726

(22) PCT Filed: Dec. 10, 2019
(86) PCT No.: PCT/CN2019/124415

§ 371 Date: Dec. 22, 2019

(30) Foreign Application Priority Data
May 11, 2019 (CN) 201911068620.8

(51) Int. Cl. H01L 27/32; H01L 51/52; H01L 51/56

(52) U.S. Cl. CPC H01L 27/3246; H01L 51/5237; H01L 51/56; H01L 51/5234

(57) ABSTRACT

An organic light-emitting diode (OLED) display panel is disclosed. The OLED display panel includes a substrate, a pixel definition layer disposed on the substrate and configured to define a plurality of pixel units, wherein at least one first groove extending along a first direction is disposed on a side of the pixel definition layer away from the substrate; and a metal member is disposed in the first groove, and the metal member is electrically connected to a transparent cathode.

The present application claims priority from a Chinese patent application filed with the Chinese Patent Office on Nov. 5, 2019, with application number 201911068620.8, and application name is “OLED DISPLAY PANEL”, the entire contents of which are incorporated herein by reference.

### FIELD OF INVENTION

The present application relates to the field of display technologies, and in particular, to an organic light-emitting diode (OLED) display panel.

### BACKGROUND OF INVENTION

Top emission organic light-emitting diode (OLED) display panels have broad application prospects, but top emission OLED display panels require a top electrode (cathode) having a certain high transparency. If a metal such as a magnesium-silver alloy is used as the top electrode, its thickness must be controlled in a range of less than 20 nm. However, in the case of such a thin metal, the cross-sectional current is greatly limited, and it exhibits poor conductivity. When this type of cathode is applied to large-sized display panels, due to the different distances of the supply circuits, the degree of voltage drop (IR drop) in different areas of the panel is different, and the area where the effect is finally displayed is uneven.

To solve this problem, an existing method is to add additional metal components in a panel area in addition to a display pixel region. In the formation of the OLED display panels, a thin transparent top electrode is connected to the metal components, and the metal components uniformly distributed on the display panel to make potentials of the thin transparent top electrode of different regions consistent. However, the problem with this technique is that metal components are often covered during an evaporation of organic materials, just like a bottom electrode in the pixel region, and finally the evaporated top electrode is difficult to make effective contact with the metal components.

Another method is to print conductive ink and dry it to form auxiliary wires to form a staggered mesh silver wire structure. This structure is connected to a thin metal cathode to solve the problem of conductivity. However, conventional conductive inks, or carbon-based conductive inks, do not have conductivity by themselves. After printing, they need to undergo certain post-processing processes such as sintering and annealing to remove solvents, dispersants, and stabilizers in conductive inks, and the conductive material can be conductive only when it forms a continuous film.

Therefore, in order to solve the above problems, a new OLED display panel is proposed.

### SUMMARY OF INVENTION

### Technical Problem

The present application provides an OLED display panel. By providing at least one first groove extending along a first direction on a side of a pixel definition layer away from the substrate, and a metal member is disposed in the first groove. The metal member is electrically connected to a transparent cathode, so that the voltage drops of different display areas of the OLED display panel are consistent, and the effect of uniform display is achieved. Moreover, the metal member is formed by printing liquid metal, which is easy to process, has good stability, can be bent and can also be applied to flexible panels, and has high electrical conductivity. It does not require additional formation of auxiliary electrodes, which simplifies the manufacturing process, and substantially improves a total aperture ratio of display pixels.

### Technical Solutions

In a first aspect, an embodiment of the present application provides an organic light-emitting diode (OLED) display panel, the OLED display panel including:

a substrate;

a pixel definition layer disposed on the substrate and configured to define a plurality of pixel units; wherein at least one first groove extending along a first direction and at least one second groove extending along a second direction perpendicular to the first direction are disposed on a side of the pixel definition layer away from the substrate; and

a metal member is disposed in the first groove or the second groove, and the metal member is electrically connected to a transparent cathode.

In the OLED display panel, the transparent cathode is disposed on the pixel definition layer and covers the pixel definition layer, the first groove, and the second groove, and the metal member is disposed on the transparent cathode.

In the OLED display panel, the transparent cathode is disposed on the pixel definition layer and covers the pixel definition layer, the first groove, and the second groove, and the metal member is disposed in the first groove or the second groove.

In the OLED display panel, a plurality of the first grooves and a plurality of the second grooves are respectively disposed on the side of the pixel definition layer away from the substrate, at least one the pixel unit is spaced between two adjacent first grooves, and at least one the pixel unit is spaced between the two adjacent second grooves.

In the OLED display panel, the metal member extends to an edge of the OLED display panel and is connected to a power source at the edge of the OLED display panel.

In the OLED display panel, the metal member is made of a metal material that is a liquid status at a room temperature.

In a second aspect, an embodiment of the present application further provides an OLED display panel, including:

a substrate;

a pixel definition layer disposed on the substrate and configured to define a plurality of pixel units; wherein at least one first groove extending along a first direction is disposed on a side of the pixel definition layer away from the substrate; and

a metal member is disposed in the first groove, and the metal member is electrically connected to a transparent cathode.

In the OLED display panel, at least one second groove extending along a second direction perpendicular to the first direction is disposed on the side of the pixel definition layer away from the substrate, and the metal member is disposed in the second groove.

In the OLED display panel, the transparent cathode is disposed on the pixel definition layer and covers the pixel definition layer and the first groove or the second groove, and the metal member is disposed on the transparent cathode.

In the OLED display panel, the transparent cathode is disposed on the pixel definition layer and covers the pixel definition layer and the first groove or the second groove, and the metal member is disposed in the first groove or the second groove.

In the OLED display panel, a plurality of the first grooves are disposed on the side of the pixel definition layer away from the substrate, and at least one the pixel unit is spaced between two adjacent first grooves.

In the OLED display panel, a plurality of the second grooves are disposed on the side of the pixel definition layer away from the substrate, and at least one the pixel unit is spaced between two adjacent second grooves.

In the OLED display panel, the metal member extends to an edge of the OLED display panel and is connected to a power source at the edge of the OLED display panel.

In the OLED display panel, the metal member is made of a metal material that is a liquid status at a room temperature.

According to a third aspect, an embodiment of the present application further provides a method of manufacturing an OLED display panel, wherein the method includes:

patterning a pixel definition layer on a substrate, and etching to form at least one first groove extending along a first direction on a side of the pixel definition layer away from the substrate;

evaporating an anode, a luminous layer, and a transparent cathode sequentially on the substrate corresponding to a plurality of pixel units;

forming a metal member in the first groove, wherein the metal member is formed before the transparent cathode formed or after the transparent cathode formed; and

evaporating a protective layer and a thin film encapsulation layer sequentially and covering the transparent cathode and the metal member.

In the method of manufacturing the OLED display panel, wherein forming the metal member in the first groove includes:

printing a liquid metal in the first groove to form the metal member.

### Beneficial Effect

Compared with the conventional art, the OLED display panel provides by the present application, which provides at least one first groove extending along a first direction on a side of a pixel definition layer away from the substrate, a metal member is disposed in the first groove, and the metal member is electrically connected to a transparent cathode. As a result, the voltage drops of different display areas of the OLED display panel are consistent, and the effect of uniform display is achieved. Moreover, the metal member is formed by printing liquid metal, which is easy to process, has good stability, can be bent and can also be applied to flexible panels, and has high electrical conductivity. It does not require additional formation of auxiliary electrodes, which simplifies the manufacturing process, and substantially improves a total aperture ratio of display pixels.

### BRIEF DESCRIPTION OF FIGURES

FIG. 1 is a schematic structural diagram of an organic light-emitting diode (OLED) display panel according to the present application.

FIG. 2 is a schematic diagram of a distribution of metal components according to the present application.

FIG. 3 is a partially enlarged schematic diagram of a region A in FIG. 2.

FIG. 4 is a schematic diagram of forming a metal member by printing liquid metal.

### DETAILED DESCRIPTION OF EMBODIMENTS

The present application provides an organic light-emitting diode (OLED) display panel. In order to illustrate the technical solutions of the present disclosure or the related art in a clearer manner, the drawings desired for the present disclosure or the related art will be described hereinafter briefly. It should be understood that following drawings merely relate to some embodiments of the present disclosure, and are not used to limit the application.

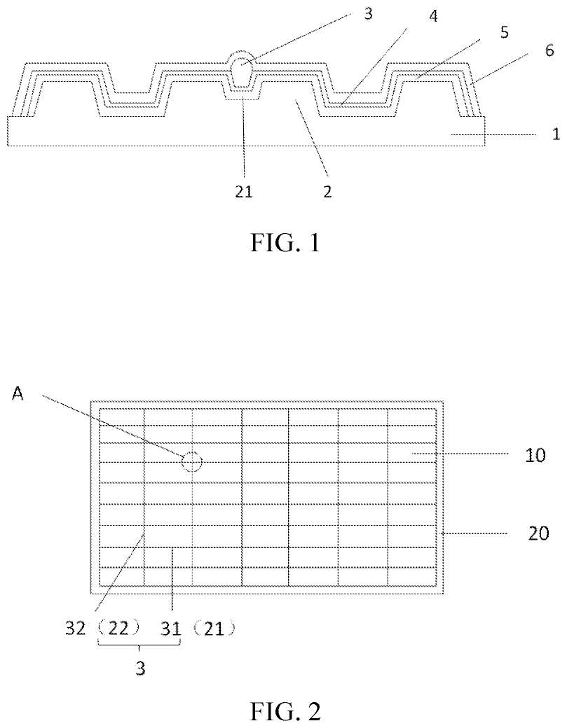

Please refer to FIGS. 1 and 2, where FIG. 1 is a schematic structural diagram of an OLED display panel of the present application, and FIG. 2 is a schematic diagram of a distribution of metal components of the present application. The present application discloses an OLED display panel, in one embodiment, the OLED display panel includes a substrate 1, a pixel definition layer 2 disposed on the substrate 1 and configured to define a plurality of pixel units, wherein at least one first groove 21 extending along a first direction is disposed on a side of the pixel definition layer 2 away from the substrate 1, at least one second groove 22 extending along a second direction perpendicular to the first direction is disposed on the side of the pixel definition layer 2 away from the substrate 1, a metal member 3 is disposed in the first groove 21 and the second groove 22, and the metal member 3 is electrically connected to a transparent cathode 4.

Continuing refer to FIG. 1 and FIG. 2, the transparent cathode 4 is disposed on the pixel definition layer 2 and covers the pixel definition layer 2, the first groove 21, and the second groove 22, and the metal member 3 is disposed on the transparent cathode 4. A cross-sectional shape of the first groove 21 and the second groove 22 is trapezoidal.

In other embodiments, the transparent cathode 4 is disposed on the pixel definition layer 2 and covers the pixel definition layer 2, the first groove 21 or the second groove 22, and covers the metal member 3 disposed in the first groove 21 and the second groove 22.

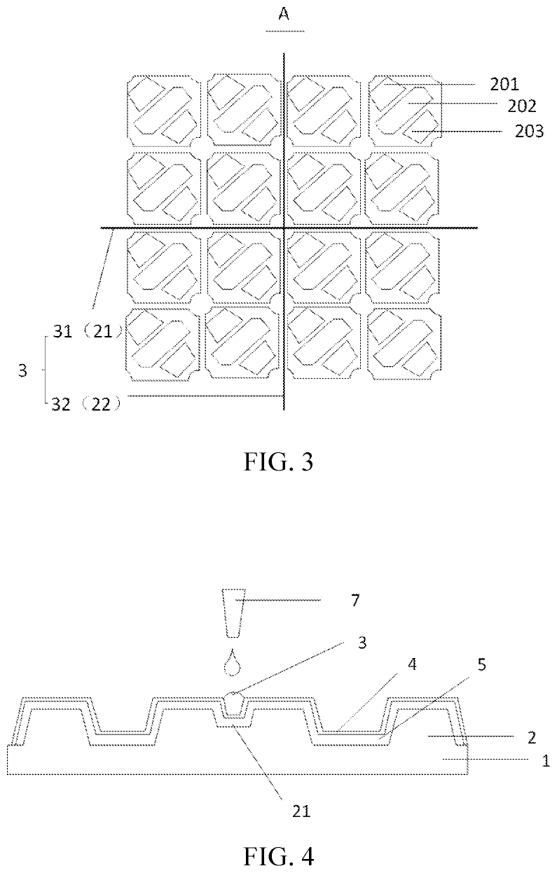

Referring to FIG. 3, where FIG. 3 is a partially enlarged schematic diagram of a region A in FIG. 2. In this embodiment, a plurality of the first grooves 21 and a plurality of the second grooves 22 are disposed on the side of the pixel definition layer 2 away from the substrate 1 in the same time, at least one the pixel unit is spaced between two adjacent first grooves 21, and at least one the pixel unit is spaced between the two adjacent second grooves 22. The pixel units include a red pixel unit 201, a blue pixel unit 202, and a green pixel unit 203. Specifically, the metal member 3 includes a plurality of first direction wires 31 and a plurality of second direction wires 32. The first direction wires 31 correspond to the first grooves 21 one by one. The second direction wires 32 correspond to the second grooves 22 one by one. One of the first direction wires 31 is disposed for each m-th row of pixel units, and one of the second direction wires 32 is disposed for each n-th column of pixel units, where each m and n is a natural number greater than 1.

Continuing refer to FIG. 1 and FIG. 2, the metal member 3 is uniformly covered in a display area 10 of the OLED display panel in a mesh structure. An input end of the transparent cathode 4 extends to a peripheral area 20. In this embodiment, the display area 10 has a rectangular shape, the peripheral area 20 surrounds the display area 10, the metal members 3 are evenly distributed in the display area 10, and the metal members 3 extend to an edge of the OLED display panel and are connected to a power source at the edge of the OLED display panel.

Continuing refer to FIG. 1, where a light-emitting element is disposed in the pixel unit. The light-emitting element includes an anode (not shown) disposed on the substrate 1, a luminous layer 5 disposed on the anode, the transparent cathode 4 disposed on the luminous layer 5, and a protective layer (not shown) covered the transparent cathode 4. The OLED display panel further includes a thin film encapsulation layer 6, and thin film encapsulation layer 6 covers the protective layer.

In an embodiment of the present application, the material of the metal member 3 is a metal material which is in a liquid status at room temperature, and the liquid metal is a gallium indium alloy (EGaln: Ga75.5In24.5, melting point: 17° C.).

Referring to FIG. 4, where FIG. 4 is a schematic diagram of forming the metal member by printing the liquid metal. The present application also provides a method of manufacturing the OLED display panel. The manufacturing method includes:

S01, patterning a pixel definition layer 2 on a substrate 1, and etching to form at least one first groove 21 extending along a first direction on a side of the pixel definition layer 2 away from the substrate;

S02, evaporating an anode, a luminous layer 5, and a transparent cathode 4 sequentially on the substrate 1 corresponding to a plurality of pixel units; and forming a metal member 3 in the first groove 21, wherein the metal member 3 is formed before the formation of the transparent cathode or after the formation of the transparent cathode.

The step of forming the metal member 3 in the first groove 21 specifically includes: printing a liquid metal in the first groove 21 by a printing device 7 to form the metal member 3.

By printing the liquid metal to form the metal member 3, there is no need to perform a post-processing process after printing is completed, such as sintering, annealing, etc., which will damage an underlying organic material, and the conductive function can be realized.

S03, evaporating a protective layer and a thin film encapsulation layer 6 sequentially and covering the transparent cathode 4 and the metal member 3.

In this step, since the liquid metal is in the liquid status at room temperature, the OLED display panel needs to be placed on a cooling plate, and a surface temperature of the cooling plate is set to a temperature that can freeze the liquid metal, such as 0° C.

In other embodiments of the present application, the method of manufacturing an OLED display panel can be used to form at least one second groove 22 extending along the second direction.

In another embodiment of the present application, by using the method of manufacturing an OLED display panel, at least one first groove 21 extending along the first direction and at least one second groove 22 extending along the second direction can be formed in the same time.

Continuing refer to FIG. 1, where the OLED display panel according to the embodiment of the present application, in order to obtain a high transparency, the transparent cathode 4 of the OLED display panel is set as an extremely thin metal layer, and the impedance of the transparent cathode 4 is larger. Through a parallel contact between the transparent cathode 4 and the metal member 3 in the present application, the contact resistance between the transparent cathode 4 and the metal member 3 is reduced, therefore, the voltage of the transparent cathode 4 can be reduced more, and the actual voltage of the transparent cathode 4 is closer to the input voltage, so that the resistances everywhere on the transparent cathode 4 can be more uniform, that is, the resistances of the transparent cathodes 4 at different positions can be made the same within a tolerance range, and the voltage drops of the transparent cathodes 4 at different positions can be made the same within an allowable tolerance range, so that the influence caused by the voltage drops can be improved, and the purpose of improving display uniformity is achieved.

The OLED display panel is also suitable for a top emission OLED display panel, especially for a large-sized top emission OLED device structure. In the top emission OLED display panel, the transparent cathode 4 is a top electrode, and the material of the transparent cathode 4 is an ITO electrode.

For specific implementation of the foregoing operations, refer to the foregoing embodiments, and details are not described herein again.

In summary, in the present application, a plurality of first grooves 21 and second grooves 22 are disposed on a side of the pixel definition layer 2 away from the substrate 1, and a metal member 3 is disposed in the first grooves 21 and the second grooves 22. The metal member 3 is electrically connected to a transparent cathode 4, and the metal member 3 extends to an edge of the OLED display panel and is connected to a power source at the edge of the OLED display panel, so that the IR drop of the transparent cathode 4 of the OLED display panel are consistent and to make the voltage of the transparent cathode 4 more uniform, and the effect of uniform display of the display area 10 is achieved. Moreover, the metal member is formed by printing liquid metal, which is easy to process, has good stability, can be bent and can also be applied to flexible panels, and has high electrical conductivity. It does not require additional formation of auxiliary electrodes, which simplifies the manufacturing process, and substantially improves a total aperture ratio of display pixels.

It can be understood that for a person of ordinary skill in the art, equivalent replacements or changes can be made according to the technical solution of the present application and its application concept, and all these changes or replacements should fall within the protection scope of the claims attached to the present application.

What is claimed is:

1. An organic light-emitting diode (OLED) display panel, comprising:
a substrate;
a pixel definition layer disposed on the substrate and configured to define a plurality of pixel units; wherein at least one first groove extending along a first direction and at least one second groove extending along a second direction perpendicular to the first direction are disposed on a side of the pixel definition layer away from the substrate; and
a metal member is disposed in the first groove or the second groove, and the metal member is electrically connected to a transparent cathode.

2. The OLED display panel according to claim 1, wherein the transparent cathode is disposed on the pixel definition layer and covers the pixel definition layer, the first groove, and the second groove, and the metal member is disposed on the transparent cathode.

3. The OLED display panel according to claim 1, wherein the transparent cathode is disposed on the pixel definition layer and covers the pixel definition layer, the first groove, and the second groove, and the metal member is disposed in the first groove or the second groove.

4. The OLED display panel according to claim 1, wherein a plurality of the first grooves and a plurality of the second grooves are respectively disposed on the side of the pixel definition layer away from the substrate, at least one the pixel unit is spaced between two adjacent first grooves, and at least one the pixel unit is spaced between the two adjacent second grooves.

5. The OLED display panel according to claim 1, wherein the metal member extends to an edge of the OLED display panel and is connected to a power source at the edge of the OLED display panel.

6. The OLED display panel according to claim 1, wherein the metal member is made of a metal material that is a liquid status at a room temperature.

7. An organic light-emitting diode (OLED) display panel, comprising:
a substrate;
a pixel definition layer disposed on the substrate and configured to define a plurality of pixel units; wherein at least one first groove extending along a first direction is disposed on a side of the pixel definition layer away from the substrate; and
a metal member is disposed in the first groove, and the metal member is electrically connected to a transparent cathode.

8. The OLED display panel according to claim 7, wherein at least one second groove extending along a second direction perpendicular to the first direction is disposed on the side of the pixel definition layer away from the substrate, and the metal member is disposed in the second groove.

9. The OLED display panel according to claim 8, wherein the transparent cathode is disposed on the pixel definition layer and covers the pixel definition layer and the first groove or the second groove, and the metal member is disposed on the transparent cathode.

10. The OLED display panel according to claim 8, wherein the transparent cathode is disposed on the pixel definition layer and covers the pixel definition layer and the first groove or the second groove, and the metal member is disposed in the first groove or the second groove.

11. The OLED display panel according to claim 7, wherein a plurality of the first grooves are disposed on the side of the pixel definition layer away from the substrate, and at least one the pixel unit is spaced between two adjacent first grooves.

12. The OLED display panel according to claim 8, wherein a plurality of the second grooves are disposed on the side of the pixel definition layer away from the substrate, and at least one the pixel unit is spaced between two adjacent second grooves.

13. The OLED display panel according to claim 7, wherein the metal member extends to an edge of the OLED display panel and is connected to a power source at the edge of the OLED display panel.

14. The OLED display panel according to claim 7, wherein the metal member is made of a metal material that is a liquid status at a room temperature.

15. A method of manufacturing an organic light-emitting diode (OLED) display panel, wherein the method comprises:
patterning a pixel definition layer on a substrate, and etching to form at least one first groove extending along a first direction on a side of the pixel definition layer away from the substrate;
evaporating an anode, a luminous layer, and a transparent cathode sequentially on the substrate corresponding to a plurality of pixel units;
forming a metal member in the first groove, wherein the metal member is formed before the transparent cathode formed or after the transparent cathode formed; and
evaporating a protective layer and a thin film encapsulation layer sequentially and covering the transparent cathode and the metal member.

16. The method of manufacturing the OLED display panel according to claim 15, wherein forming the metal member in the first groove comprises:
printing a liquid metal in the first groove to form the metal member.
